(19) United States
(12) Patent Application Publication
(10) Pub. No.: US 2011/0240088 A1
(43) Pub. Date: Oct. 6, 2011

(54) ONE-PIECE JUNCTION BOX

(75) Inventor: Robert Donald ECOB, Cambridge (CA)

(73) Assignee: ATS Automation Tooling Systems Inc., Cambridge (CA)

(21) Appl. No.: 13/075,815

(22) Filed: Mar. 30, 2011

Related U.S. Application Data
(60) Provisional application No. 61/319,693, filed on Mar. 31, 2010.

(51) Int. Cl. H01L 31/042; H05K 5/00; H05K 5/06; H02G 3/18; B29C 45/00; B29C 45/14

(52) U.S. Cl. 136/244; 174/50; 174/50.5; 174/59; 264/328.1; 264/272.14

(57) ABSTRACT

A junction box comprising: a back wall and at least one side wall integrally formed as a single unit, the back wall supported by the at least one side wall, wherein the back wall and side wall define an inner cavity when the junction box is placed against a surface; and one or more pass holes formed on at least one of the back wall and side wall for providing access to the inner cavity when the junction box is placed against the surface.

### CROSS REFERENCE TO RELATED APPLICATIONS

This application claims the benefit of priority of U.S. Provisional Patent Application No. 61/319,693, filed Mar. 31, 2010, which is incorporated herein by reference in its entirety.

### FIELD

The present disclosure relates to a single piece junction box or housing body for forming an electrical connection to a product. In particular, this document relates to a junction or back box on a photovoltaic cell module.

### BACKGROUND

This document relates generally to the provision of an electrical connection to an electrical product. In order to provide an example, the case of a back box on a photovoltaic module is used as an example.

A typical photovoltaic (PV) module consists of a window material to which a matrix of solar cells has been applied (laminated or deposited) with internal connections completed by bus wires, typically flat/ribbon wire, all of which is covered by a back sheet material. In addition, the PV module will also have a junction box (sometimes called a back box) housing to provide electrical connection to outside sources.

Conventional back boxes typically include an open enclosure that allows the entry of tools to connect electrical connectors in the back box to electrical elements in the PV module and a lid or cover that is placed on the open enclosure once the electrical connections are completed. Various gaskets, compliant seals and connectors are required to seal the back box to resist penetration of moisture. Also, existing products utilize a variety of glands and Sprague-type anti-removal features to seal around wires that feed out of the back box for external electrical connections. The risk that moisture will enter into the housing is increased by the numerous gaskets, seals and connectors required. If moisture enters into the housing, corrosion of metal terminals and connectors may result and the PV module may be damaged or fail.

As such, there is need for an improved system, apparatus and method of forming and connecting a back-box to a PV module.

### SUMMARY

It is an object of the present disclosure to eliminate or mitigate at least one disadvantage of previous junction boxes.

In one aspect, a single piece junction box housing is provided that is configured such that no separate lid, cover or the like is required.

In another aspect, an internal chamber of the junction box housing is filled with an inert gas, such as the noble gases, Xenon, Neon and such. The use of an inert gas would provide similar protection to but only require a very short application time when compared to the insertion of conventional UV or skin-cure thermoset potting. In this case, the internal chamber can be filled with the inert gas through pass holes, and the pass holes can then be heat/friction sealed after assembly to provide hermetic sealing of the internal chamber.

Alternatively, the internal chamber can be filled with potting material through pass holes, and the pass holes can then be heat/friction sealed after assembly to provide hermetic sealing of the internal chamber.

According to one aspect herein, there is provided a junction box comprising: a back wall and at least one side wall integrally formed as a single unit, the back wall supported by the at least one side wall, wherein the back wall and side wall define an inner cavity when the junction box is placed against a surface; and one or more pass holes formed on at least one of the back wall and side wall for providing access to the inner cavity when the junction box is placed against the surface.

The pass holes provide openings for the insertion of tools for, for example, connecting electrical connections in the junction box to electrical connections on or in the surface that the junction box is provided to. The pass holes can also be used to insert inert gas or potting into the inner cavity as detailed herein.

In a particular case, the back wall may be square or rectangular and the at least one side wall comprises four side walls integrally formed with the back wall.

In another case, a flange may extend from the at least one side wall and is configured to conform to the surface. In this case, the flange may have a recess configured to receive a sealing agent to seal the junction box to the surface.

In yet another case, the pass holes may comprise heat sealing pipes.

In still another case, the pass holes may be configured to be sealed by a rotary heated reflow process.

In another case, the junction may further comprise an inert gas provided to the inner cavity via the pass holes after the junction box has been placed against the surface.

In still another case, the junction may further comprise one or more electrical connectors integrally connected into at least one of the back wall and side wall. In this case, the one or more electrical connectors may be integrally connected by insertion molding.

The embodiments of the junction box described herein may be particularly applicable to junction boxes (back boxes) for photovoltaic modules.

According to another aspect herein, there is provided a method of manufacturing a junction box comprising; integrally forming a back wall and side wall, the back wall supported by the at least one side wall, wherein the back wall and side wall define an inner cavity when the junction box is placed against a surface; and integrally forming one or more pass holes on at least one of the back wall and the side wall for providing access to the inner cavity when the junction box is placed against the surface.

In a particular case, the back wall, side wall and pass holes are formed by injection molding.

In another case, the method may further comprise: sealing the junction box against the surface; filling the inner cavity with an inert gas; and sealing the pass holes.

In another case, the method may further comprise integrally connecting one or more electrical connectors into at least one of the back wall and side wall. In this case, the integrally connecting the one or more electrical connectors may be by insertion molding.

Other aspects and features of the present disclosure will become apparent to those ordinarily skilled in the art upon review of the following description of specific embodiments in conjunction with the accompanying figures.

### BRIEF DESCRIPTION OF THE DRAWINGS

For a better understanding of the embodiments described herein and to show more clearly how they may be carried into effect, reference will now be made, by way of example only, to the accompanying drawings which show the exemplary embodiments and in which:

FIG. 1 shows a single piece housing body in perspective view from a top side;

FIG. 2 shows the single piece housing body shown in FIG. 1 from a bottom side;

FIG. 3 shows the single piece housing body of FIG. 1 where the housing body is shown transparent;

FIG. 4 shows a cross-section of the single piece housing body of FIG. 3; and

FIG. 5 shows a side view of the single piece housing body shown in FIG. 3.

### DETAILED DESCRIPTION

It will be appreciated that for simplicity and clarity of illustration, where considered appropriate, reference numerals may be repeated among the figures to indicate corresponding or analogous elements or steps. In addition, numerous specific details are set forth in order to provide a thorough understanding of the exemplary embodiments described herein. However, it will be understood by those of ordinary skill in the art that the embodiments described herein may be practiced without these specific details. In other instances, well-known methods, procedures and components have not been described in detail so as not to obscure the embodiments described herein. Furthermore, this description is not to be considered as limiting the scope of the embodiments described herein in any way, but rather as merely describing the implementation of the various embodiments described herein.

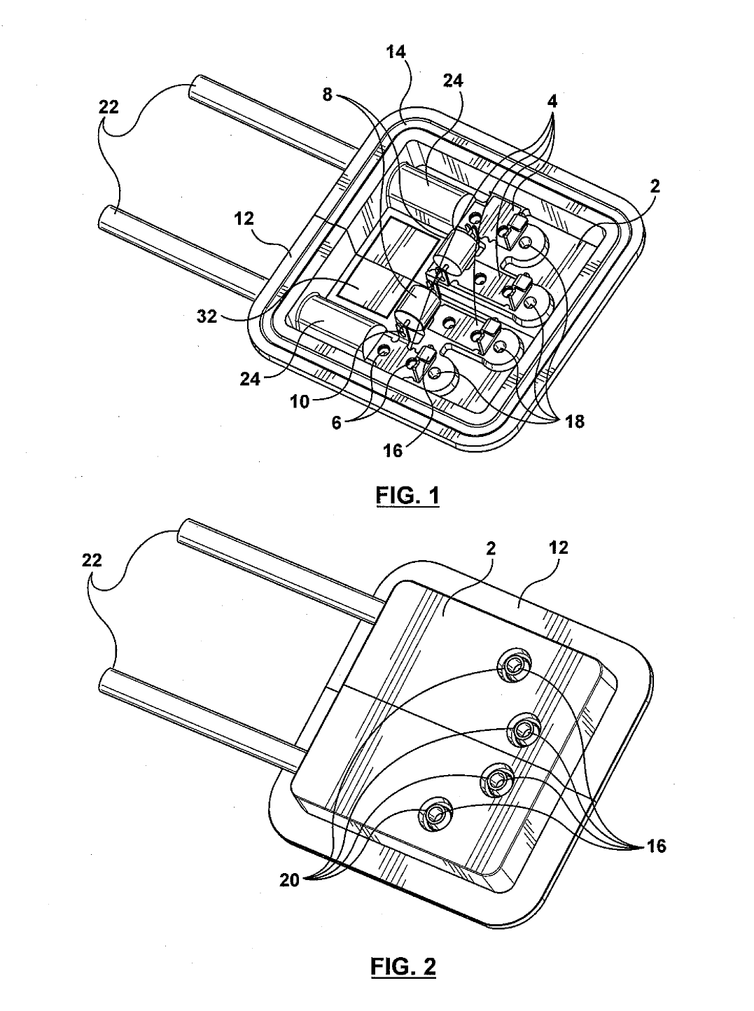

FIG. 1 shows a bottom view of a single piece junction box housing body 2. FIG. 2 shows a top view of the junction box housing body 2. The body 2 can be molded, for example, injection or compression molded, out of an engineering resin, such as, for example, Thermoplastic Polyphenylene Oxide (PPO) or thermoset material. Other molding methods and materials may also be available. The body 2 houses electrical components which assist with the power conversion and electrical power collection of a PV module and photovoltaic cells.

Leadframe/terminals 4 are used to connect the junction box to a PV module (not shown). In assembly, the leadframe/terminals 4 can be stamped as attached clusters and then singulated using in-mold excising and retracting pin techniques. The leadframe/terminals 4 shown in FIG. 1 include alignment features L for in-mold placement and control under injection or compression pressures.

Diodes 8 can optionally be provided, but may only be required depending on the configuration of power management of the PV module or photovoltaic cell. Connectors 10 (for example IDC or similar) can be provided to connect the diodes 8 and can be soldered if desired or necessary.

The junction box is connected to a PV module or solar panel (not shown) by placing the junction box housing body 2 on the PV module and a seal is provided along the sealant recess 12 of the housing flange 14 using adhesive sealant such as silicone. Other sealants or sealant systems may also be used in this location.

Terminal ribbon connector tabs 16 of the terminals 4 are made to a PV module connector such as a ribbon or bus wire (not shown) by inserting a tool through pass holes 18 after the body 2 is sealed to the PV module. For example, the terminal ribbon connector tabs 16 can be connected by soldering, but can also be connected by a dry joint, riveting, or laser welding. This can include re-flow solder scavenging or pre-tinned solder pads.

Once the terminal ribbon connector tabs 16 are connected, joint inspection and testing can be conducted. Once complete, a potting compound can be injected into the cavity between the PV module and the body 2 through the pass holes 18 (shown from the exterior in FIG. 2). This is done to fill void air space in the cavity and is intended to reduce or prevent damage that may be caused by the presence or entry of undesirable matter such as moisture or the like.

As an alternative to potting material, a gas such as Xenon, Neon, or other noble inert gases can be flowed into the cavity through the pass holes 18. Because the noble inert gas is heavier than air, the gas will flow down into the void space, or, in some cases, a predetermined level of pressure may be used.

Following insertion of the potting material or inert gas, the pass holes 18 are sealed to form a hermetically sealed product. In particular, the pass holes may be sealed by a rotary heated reflow process. Because the noble gases are inert, they are not affected by the heat of the reflow. Also, by having inert gas in the cavity, metallic parts such as connector tabs are protected.

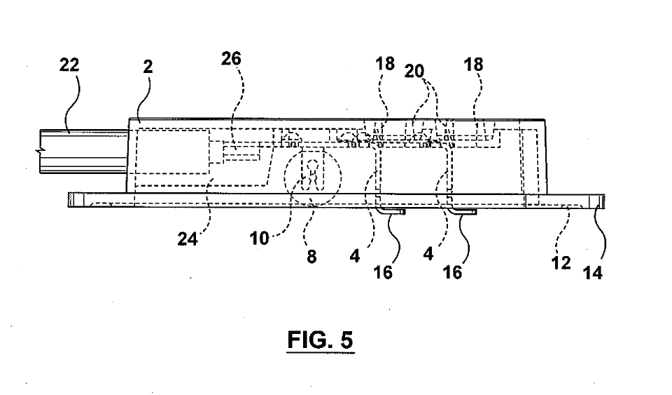

As shown in FIGS. 2, 4 and 5, the pass holes 18 are provided with heat sealing pipes 20. The heat sealing pipes 20 assist with the rotary heated reflow process in that the heat sealing pipes can be heated with a rotating female conical heated mandrel such that they collapse inwards to reflow into igloo-shaped geometry, hermetically and permanently sealing the pass holes 18 and the main chamber of the back box.

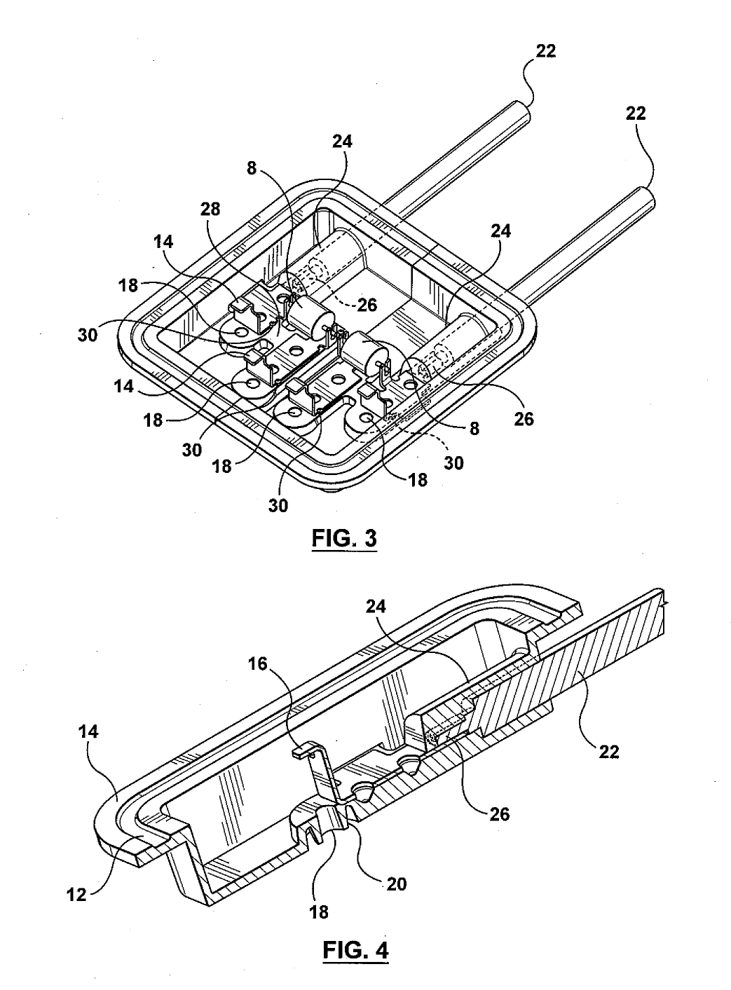

Main power cables 22 are shown in FIG. 1. As shown, the body 2 is molded (e.g. injection or compression) with integrally over-molded main electrical cables 22. This can be visualized in FIGS. 3 and 4 where the injection over-molded area 24 can also include retracting-core cable distortion methods to enhance cable-retention against pull-forces. Insert-injection molding or compression molding technology can be used to capture the terminals in a single operation, eliminating post-assembly operations.

It is also possible to insert mold a single-piece terminal cluster/leadframe (that is, a plurality of leadframes 4), and singulate individual traces/circuits 4 during the molding process with in-mold excising. This results in die-cost savings and simplification of handling. This can be done with tiebar slug retention or removal. As shown in FIG. 4, the leadframe 4/power cable 22 connection 26 is a mechanical crimp which can also be soldered.

FIG. 3 also illustrates an in-mold excising area 28 for removal of tiebars between traces or terminals 4 which can be “suspended slug” or slug-out design.

Reference character 30 in FIG. 3 is a formed or cut geometry in the inserts/terminals 4 to anchor them securely into the molded housing 2 after molding.

As shown in FIG. 1, an empty space 32 is also provided which enables addition of other components, for example, diode replacement with PCB inverters and pre-programmed intelligence such as power management, AC/DC conversion and control, wireless reporting, and the like.

From the foregoing, it will be understood that a method of making a junction box may include integrally forming a back wall and side wall, the back wall supported by the at least one side wall, wherein the back wall and side wall define an inner cavity when the junction box is placed against a surface; and integrally forming one or more pass holes on at least one of the back wall and the side wall for providing access to the inner cavity when the junction box is placed against the surface.

The method may further comprise: sealing the junction box against the surface; filling the inner cavity with an inert gas; and sealing the pass holes.

The junction box, i.e. the back wall, side wall and pass holes may be formed by any appropriate molding process, including injection molding and compression molding.

The method may further comprise integrally connecting one or more electrical connectors into at least one of the back wall and side wall. In this case, the integrally connecting the one or more electrical connectors may be by insertion molding.

Although this disclosure has described and illustrated certain embodiments, it is also to be understood that the system, apparatus and method described is not restricted to these particular embodiments. Rather, it is understood that all embodiments which are functional or mechanical equivalents of the specific embodiments and features that have been described and illustrated herein are included.

It will be understood that, although various features have been described with respect to one or another of the embodiments, the various features and embodiments may be combined or used in conjunction with other features and embodiments as described and illustrated herein.

What is claimed is:

1. A junction box comprising:
a back wall and at least one side wall integrally formed as a single unit, the back wall supported by the at least one side wall, wherein the back wall and side wall define an inner cavity when the junction box is placed against a surface; and
one or more pass holes formed on at least one of the back wall and side wall for providing access to the inner cavity when the junction box is placed against the surface.

2. The junction box of claim 1, wherein the back wall is square or rectangular and the at least one side wall comprises four side walls integrally formed with the back wall.

3. The junction box of claim 1, wherein a flange extends from the at least one side wall and is configured to match to the surface.

4. The junction box of claim 3, wherein the flange has a recess configured to receive a sealing agent to seal the junction box to the surface.

5. The junction box of claim 1, wherein the pass holes comprise heat sealing pipes.

6. The junction box of claim 1, wherein the pass holes are configured to be sealed by a rotary heated reflow process.

7. The junction box of claim 1, further comprising an inert gas provided to the inner cavity via the pass holes after the junction box has been placed against the surface.

8. The junction box of claim 1, further comprising one or more electrical connectors integrally connected into at least one of the back wall and side wall.

9. The junction box of claim 8, wherein the one or more electrical connectors are integrally connected by insertion molding.

10. The junction box of claim 1, wherein the junction box is for a photovoltaic module.

11. A photovoltaic module comprising the junction box of claim 1.

12. A method of manufacturing a junction box comprising;
integrally forming a back wall and side wall, the back wall supported by the at least one side wall, wherein the back wall and side wall define an inner cavity when the junction box is placed against a surface; and
integrally forming one or more pass holes on at least one of the back wall and the side wall for providing access to the inner cavity when the junction box is placed against the surface.

13. The method of claim 12, wherein the back wall, side wall and pass holes are formed by injection molding.

14. The method of claim 12, further comprising:
sealing the junction box against the surface;
filling the inner cavity with an inert gas; and
sealing the pass holes.

15. The method of claim 12, further comprising integrally connecting one or more electrical connectors into at least one of the back wall and side wall.

16. The method of claim 15, wherein the integrally connecting the one or more electrical connectors is by insertion molding.
